(19) United States
(12) Patent Application Publication
(10) Pub. No.: US 2007/0037368 A1
(43) Pub. Date: Feb. 15, 2007

(54) Method of fabricating a semiconductor device

(75) Inventor: Seung-Hwan Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/501,567

(22) Filed: Aug. 9, 2006

(30) Foreign Application Priority Data
Aug. 10, 2005 (KR) 10-2005-0073441

(51) Int. Cl. H01L 21/22; H01L 21/38

(52) U.S. Cl. 438/542

(57) ABSTRACT

A method of fabricating a semiconductor device includes a processing step of high-energy ion implantation. After performing the high-energy ion implantation process and before beginning a thermal process, a buffer layer is partially removed together with particles or contaminants that may be generated from the ion implantation process. Surface defects on a semiconductor substrate are prevented from occurring by diffusion of the contaminants during the thermal process.

### CROSS-REFERENCE TO RELATED APPLICATIONS

This U.S. non-provisional patent application claims priority to Korean Patent Application No. 10-2005-0073441, filed in the Korean Intellectual Property Office on Aug. 10, 2005, the entire contents of which are hereby incorporated by reference in their entirety.

### BACKGROUND

The subject matter described herein is concerned with methods of fabricating semiconductor devices, and in particular relates to a method of fabricating a semiconductor device by means of an ion implantation process with high energy.

While fabricating a semiconductor device, an ion implantation process with high energy is used in forming deep wells in a semiconductor substrate. Such deep wells may be provided to apply voltages to bulks of the semiconductor substrate by blocks or pages in a dynamic RAM or flash memory, functioning to isolate pocket wells from the substrate.

A conventional way of forming a deep well is as follows. First, a buffer layer and a photoresist pattern are formed on a semiconductor substrate. Then, with the photoresist pattern as an ion implantation mask, impurities are deeply implanted (or injected) into the semiconductor substrate at high energy. After removing the photoresist pattern, a thermal operation is performed to activate the injected impurities, resulting in the deep well.

It is not uncommon for the high-energy ion implantation process to perform a hard baking operation to the photoresist pattern, because the photoresist pattern is generally layered to a thickness over 2 μm for sufficient blocking function and the hard baking operation to such a thick photoresist layer would incur an effect of sidewall flow on the photoresist layer. If the high-energy ion implantation process is performed with the photoresist pattern without hard baking, there would be generated hydrogen (H₂), nitrogen (N₂), and carbon monoxide (CO). Although the photoresist pattern has been hard baked, such gases would be generated therein.

The high energy for the ion implantation may force the generated carbon monoxide (CO) to penetrate into the upper portion of the buffer layer. The carbon monoxide (CO) particles are diffused during the thermal treatment, reaching the semiconductor substrate, and oxygen (O) particles of the carbon monoxide react with the semiconductor substrate to form a silicon oxide layer. This silicon oxide layer is abandoned while removing the buffer layer that is made of oxide, generating concave pits on the semiconductor substrate.

Additionally, during the high-energy ion implantation process, the upper portion of the buffer layer may be damaged by such high energy. As a result, there would be caused destruction of lattices between silicon and oxygen atoms at the upper portion of the buffer layer. Then, the upper portion of the buffer layer, including the destructed lattices, may be exposed to varieties of contaminants such as pollution generated in the chamber carrying out the ion implantation process, or by-products from the photoresist pattern, as well as the carbon monoxide particles. These contaminants may be diffused in the subsequent thermal processing steps, causing more defects in the semiconductor substrate. Further, the contaminants would be highly generated after completing the high-energy ion implantation process, degrading the reliability of the semiconductor device.

### SUMMARY OF THE INVENTION

The invention is directed to a method of fabricating a semiconductor device free from surface defects even while performing a process of high-energy ion implantation.

The method of the invention includes a processing step of high-energy ion implantation. After performing the high-energy ion implantation process and before beginning a thermal process, a buffer layer is partially removed together with particles or contaminants that may be generated from the ion implantation process. This prevents surface defects on a semiconductor substrate from arising by diffusion of the contaminants during the thermal process. The contaminants are of various kinds, such as carbon monoxides, by-products of photoresist patterns, inert gases, or other impurities, which are diffused during subsequent thermal processing steps, causing surface defects on the semiconductor substrate.

In one aspect, the present invention is directed to a method of fabricating a semiconductor device, comprising: forming a buffer layer on a semiconductor substrate; implanting first impurities into the semiconductor substrate; removing the buffer layer by a predetermined thickness; and performing a thermal process to activate the implanted first impurities.

In one embodiment, the method further comprises: forming a photoresist pattern on the buffer layer before implanting the first impurities into the semiconductor substrate; and removing the photoresist pattern before partially removing the buffer layer by a predetermined thickness. Implanting the first impurities into the semiconductor substrate uses the photoresist pattern as an ion implantation mask.

In another embodiment, the method further comprises: forming a photoresist pattern on the buffer layer before implanting the first impurities into the semiconductor substrate; and removing the photoresist pattern after partially removing the buffer layer by a predetermined thickness. Implanting the first impurities into the semiconductor substrate uses the photoresist pattern as an ion implantation mask. Removing the buffer layer by the predetermined thickness uses the photoresist pattern as an etch mask.

In another embodiment, the buffer layer contains contaminants.

In another embodiment, the predetermined thickness is 10˜60% of the whole thickness of the buffer layer.

In another embodiment, the step of implanting the first impurities into the semiconductor substrate is carried out at an energy over 800 KeV.

In another embodiment, the method further comprises, after performing the thermal process,: removing a remnant portion of the buffer layer from the semiconductor substrate and exposing the semiconductor substrate; forming a gate insulation layer on the exposed semiconductor substrate; forming a gate pattern on the gate insulation layer; and forming source/drain regions adjacent to the gate pattern in the semiconductor substrate.

In another embodiment, the step of removing the buffer layer by the predetermined thickness is carried out by a wet or dry etching process.

In another embodiment, the first impurities are N-type, wherein implanting the first impurities into the semiconductor substrate comprises forming an N-type deep well.

In another embodiment, before removing the buffer layer by the predetermined thickness, the method further comprises; implanting second impurities into the semiconductor substrate at an energy lower than energy for implanting the first impurities into the semiconductor substrate.

In another embodiment, the energy for the implantation of the second impurities is in a rangeof 100˜799 KeV.

In another embodiment, the method further comprising cleaning a remaining portion of the buffer layer before performing the thermal process.

In another aspect, the present invention is directed to a method of fabricating a semiconductor device, comprising: forming a buffer layer on a semiconductor substrate; forming a photoresist pattern on the buffer layer; implanting first impurities into the semiconductor substrate using the photoresist pattern as an ion implantation mask; removing the buffer layer by a predetermined thickness; and performing a thermal process to activate the implanted first impurities.

In one embodiment, the method further comprises: removing the photoresist pattern before removing the buffer layer by the predetermined thickness.

In another embodiment, the method further comprises: removing the photoresist pattern after removing the buffer layer by the predetermined thickness. Implanting the first impurities into the semiconductor substrate uses the photoresist pattern as an ion implantation mask. Removing the buffer layer by the predetermined thickness uses the photoresist pattern as an etch mask.

In another embodiment, the buffer layer contains contaminants.

In another embodiment, the predetermined thickness is 10˜60% of the whole thickness of the buffer layer.

In another embodiment, the step of implanting the first impurities into the semiconductor substrate is carried out at an energy over 800 KeV.

In another embodiment, after performing the thermal process, the method further comprises: removing a remnant portion of the buffer layer from the semiconductor substrate and exposing the semiconductor substrate; forming a gate insulation layer in the exposed semiconductor substrate; forming a gate pattern on the gate insulation layer; and forming source/drain regions adjacent to the gate pattern in the semiconductor substrate.

In another embodiment, the first impurities are N-type, and implanting the first impurities into the semiconductor substrate comprises forming an N-type deep well.

In another embodiment, before removing the buffer layer by the predetermined thickness, the method further comprises; implanting second impurities into the semiconductor substrate by an energy lower than energy for implanting the first impurities into the semiconductor substrate.

In another embodiment, the method further comprises cleaning a remaining portion of the buffer layer before performing the thermal process.

In another aspect, the present invention is directed to a method of fabricating a semiconductor device, comprising: forming a buffer layer on a semiconductor substrate; forming a photoresist pattern on the buffer layer; implanting first impurities into the semiconductor substrate using the photoresist pattern as an ion implantation mask; removing the photoresist pattern to expose the whole surface of the buffer layer; etching the buffer layer by a predetermined thickness; cleaning a remaining portion of the buffer layer; and performing a thermal process to activate the implanted first impurities.

In one embodiment, the predetermined thickness is 10˜60% of the whole thickness of the buffer layer.

In another embodiment, the cleaning is performed using a chemical comprised in DIW (Deionized Water) and H₂O₂.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity. FIGS. 1 through 6 are sectional views illustrating processing steps for fabricating a semiconductor device in accordance with an embodiment of the invention.

FIG. 7 is a sectional view showing a feature of fabricating a semiconductor device in accordance with another embodiment of the invention.

FIGS. 8 through 12 are sectional views illustrating processing steps for fabricating a semiconductor device in accordance with still another embodiment of the invention.

### DETAILED DESCRIPTION OF PREFERRED EMBODIMENTS

Preferred embodiments of the present invention will be described below in more detail with reference to the accompanying drawings. In the figures, the dimensions of layers and regions are exaggerated for clarity of illustration. It will also be understood that when a layer (or layer) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Hereinafter, it will be described about an exemplary embodiment of the present invention in conjunction with the accompanying drawings.

FIGS. 1 through 6 are sectional views illustrating processing steps for fabricating a semiconductor device in accordance with an embodiment of the invention.

Referring to FIG. 1, field isolation layers 3 are formed in a semiconductor substrate 1. The field isolation layers 3 may be formed by means of, for example, a technique of shallow trench isolation (STI). A buffer layer 5 is stacked on the semiconductor substrate 1 including the field isolation layers 3. The buffer layer 5 may be made from a silicon oxide layer that is formed by thermal oxidation or chemical vapor deposition.

Referring to FIG. 2, a photoresist pattern 7 is arranged on the semiconductor substrate 1. With the photoresist pattern 7 as an ion implantation mask, first impurities 8 are implanted into the semiconductor substrate 1 in high energy, forming a first well 9. The first impurities 8 may be N-type as an example, such as phosphorous (P) or arsenic (As). The first well 9 may be a deep well. The photoresist pattern 7 may be formed at a thickness of 2 μm as an example, and treated with or without a hard bake. The high energy may be set on about 800 KeV. Under these conditions, as described above with reference to the conventional case, the high energy would generate carbon monoxides or other by-products from the photoresist pattern 7, which are pinned down as contaminants X in the buffer layer 5. Further, pollution generated in the equipment may be also injected into the buffer layer 5.

Referring to FIG. 3, the photoresist pattern 7 is removed from the buffer layer 5. The photoresist layer 7 can be removed by an ashing and stripping process.

As illustrated in FIGS. 3 and 4, a remnant buffer layer 5a results from partially removing the buffer layer 5 by a predetermined thickness T that corresponds to the buffer layer portion including the contaminants X. The predetermined thickness T may be in a range of 10˜60% of the minimum thickness in the buffer layer 5. The buffer layer portion of the predetermined thickness T may be removed by means of a wet of dry etching process. The remnant buffer layer 5a has at least a sufficient thickness to make a well, which is to be formed by diffusion of the first impurities 8 implanted thereinto during the subsequent thermal process, arranged in an optimum profile. For instance, the remnant buffer layer 5a may be over 40 Å.

Referring to FIGS. 4 and 5, a thermal process is carried out to the resultant structure with the remnant buffer layer 5a after partially removing the buffer layer 5 by the predetermined thickness T, curing lattice damages and electrically activating the implanted impurities. The thermal process is performed at a temperature of 600˜1200° C. After performing the thermal process, the remnant buffer layer 5a is removed to expose the semiconductor substrate 1. The remnant buffer layer 5a may be removed by means of a wet etching technique using fluoric acid as an example. As the remnant buffer layer 5a does not contain the contaminants X, there is no generation of surface defects on the semiconductor substrate 1 during the thermal process.

Next, referring to FIG. 6, a gate insulation layer 11 is formed on the exposed semiconductor substrate 1 by way of thermal oxidation. A gate electrode layer is deposited and patterned to form a gate electrode 13. Using the gate electrode 13 as a mask, second impurities are implanted into the semiconductor substrate 1 to from source/drain regions 14.

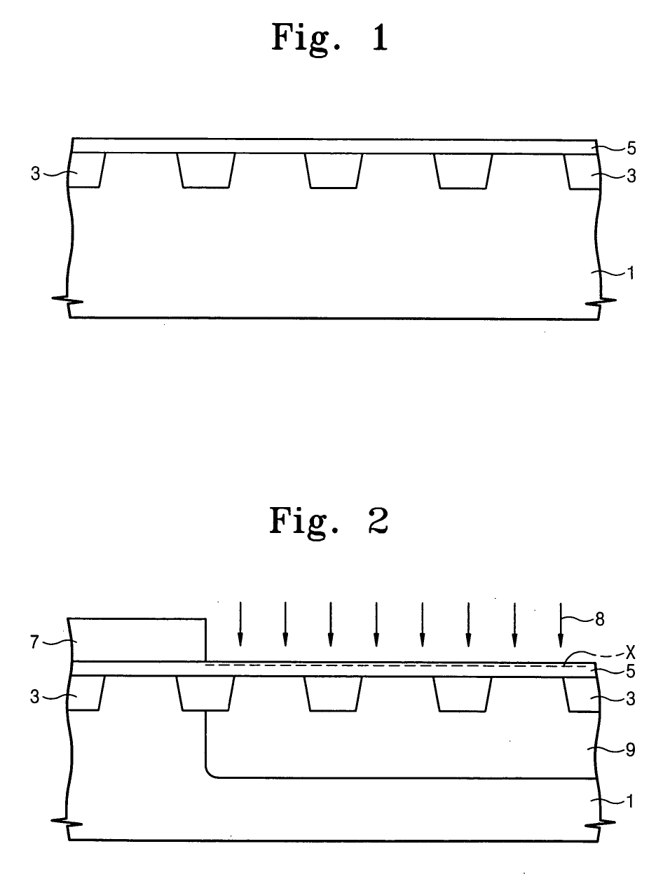

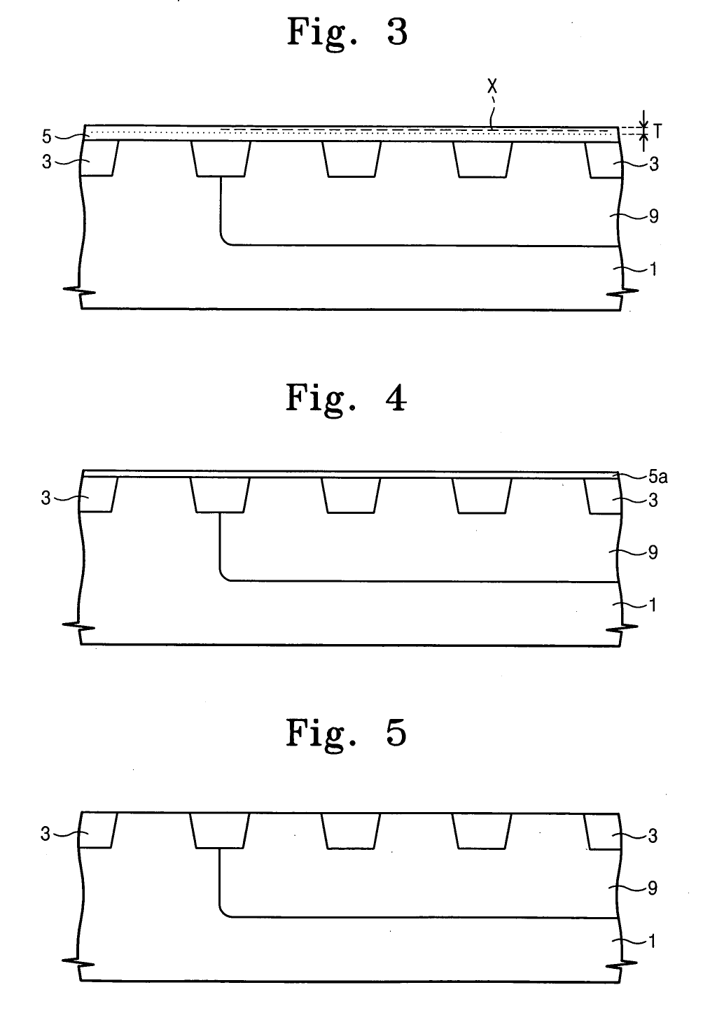

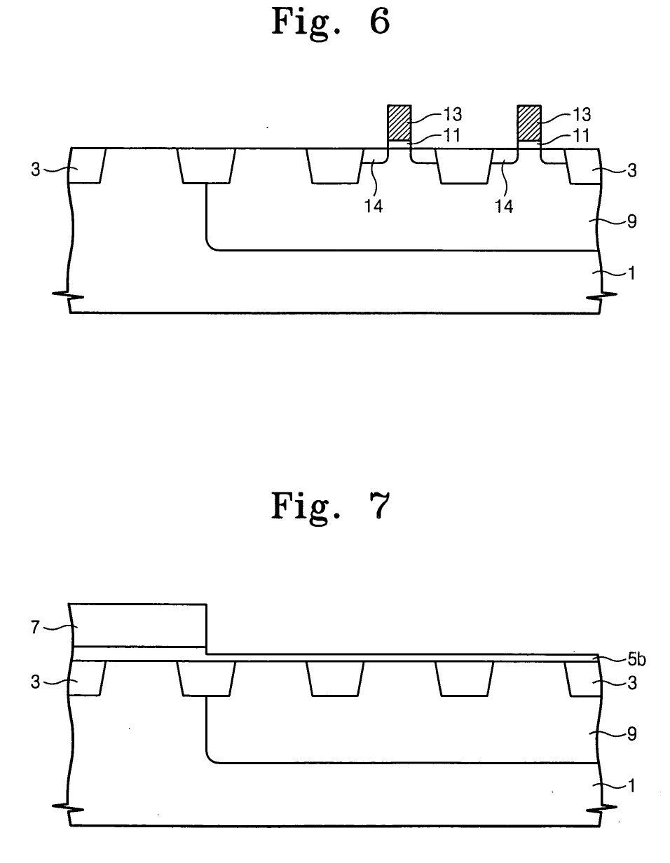

FIG. 7 is a sectional view showing a feature of fabricating a semiconductor device in accordance with another embodiment of the invention.

Referring to FIG. 7, as shown in FIG. 2, after implanting the first impurities 8 into the semiconductor substrate 1 using the photoresist pattern 7 as the mask therefor, the photoresist pattern 7 is continuously used to partially remove the buffer layer 5 by the predetermined thickness T, resulting in a remnant buffer layer 5b.

Next, after removing the photoresist pattern 7 therefrom, a thermal process is carried out to activate the first impurities 8 that have been injected into the semiconductor substrate 1. The remnant buffer layer 5b is removed therefrom to expose the semiconductor substrate 1. Subsequently, as shown in FIG. 6, the gate insulation layer 11, the gate electrode 13, and the source/drain regions 14 are formed on and in the semiconductor substrate 1.

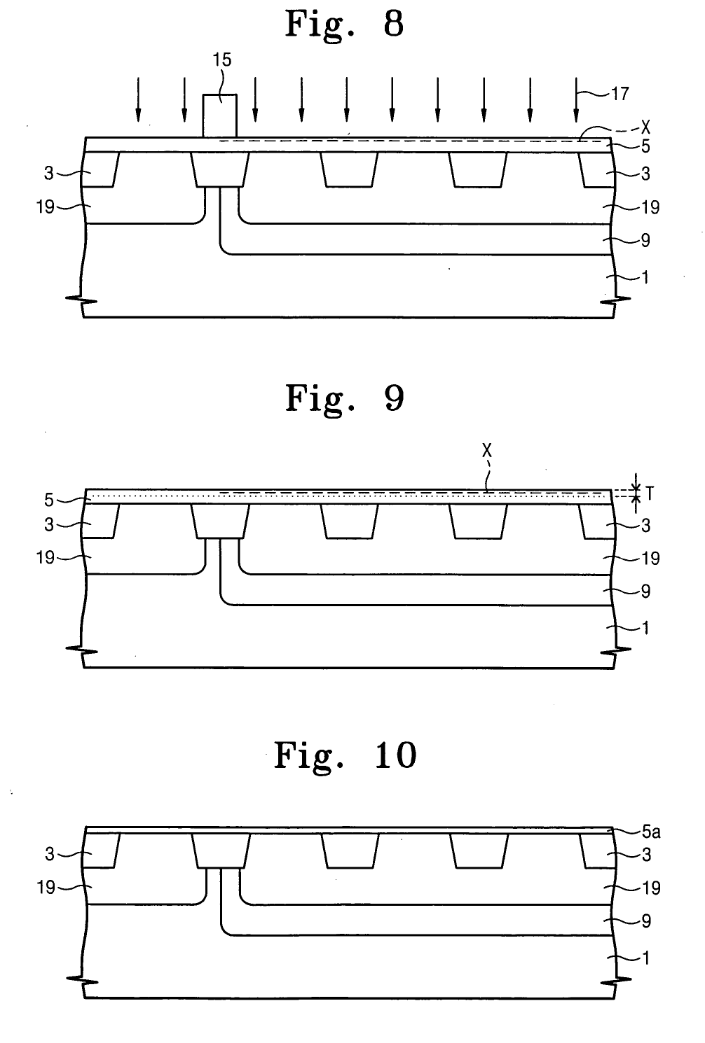

FIGS. 8 through 12 are sectional views illustrating processing steps for fabricating a semiconductor device in accordance with still another embodiment of the invention.

Referring to FIG. 8, from the structure shown in FIG. 3, a photoresist pattern 15 is arranged on the buffer layer 5, defining a second well shallower than the first well 9. Using the photoresist pattern 15 as a mask, second impurities 17 are implanted into the semiconductor substrate 1 to form the second well 19 therein. The ion implantation energy for the second well 19 is lower than that for the first well 9, e.g., in a range of 100˜799 KeV. The second impurities may be P-type, e.g., boron (B) or boron fluoride (BF₂), and the second well 19 may be a P-type well and/or a P-type pocket well surrounded by the first well 9 that is an N-type deep well. During the process of ion implantation for the second well 19, the contaminants X may be further included into the buffer layer 5.

In addition to the second well 19, it is permissible to dope a channel region or to form a channel field-stopping implantation region at the bottom areas of the field isolation layers for electrical isolation.

Referring to FIG. 9, the photoresist pattern 7 is removed therefrom. The photoresist pattern 7 may be removed by means of an ashing and stripping process.

Referring to FIGS. 9 and 10, the remnant buffer layer 5a results from partially removing the buffer layer 5 by the predetermined thickness T that corresponds to the buffer layer portion including the contaminants X. The predetermined thickness T may be in a range of 10˜60% of the minimum thickness in the buffer layer 5. The buffer layer portion of the predetermined thickness T may be removed by means of a wet of dry etching process. The remnant buffer layer 5a has at least a sufficient thickness to make a well, which is to be formed by diffusion of the first impurities 8 implanted thereinto during the subsequent thermal process, arranged in an optimum profile. For instance, the remnant buffer layer 5a may be over 40 Å.

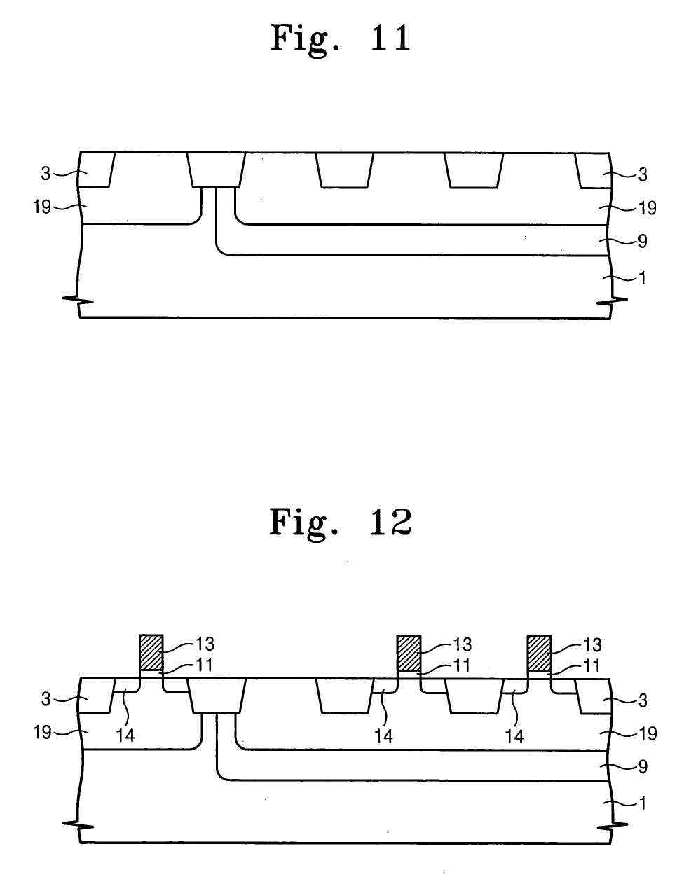

Referring to FIGS. 10 and 11, a thermal process is carried out to the resultant structure with the remnant buffer layer 5a after partially removing the buffer layer 5 by the predetermined thickness T, curing lattice damages and electrically activating the impurities 8 and 17 that have been injected into the first and second wells 9 and 19. The thermal process is performed at a temperature of 600˜1200° C. After performing the thermal process, the remnant buffer layer 5a is removed to expose the semiconductor substrate 1. The remnant buffer layer 5a may be removed by means of a wet etching technique using fluoric acid as an example.

Next, referring to FIG. 12, the gate insulation layer 11 is formed on the exposed semiconductor substrate 1 by way of thermal oxidation. The gate electrode layer is deposited and patterned to form the gate electrode 13. Using the gate electrode 13 as a mask, the second impurities are implanted into the semiconductor substrate 1 to from the source/drain regions 14.

The gate electrode 13 may be comprised of floating and control gates. Between the floating and control gates is interposed an inter-gate dielectric layer, completing a gate pattern of a flash memory cell. Otherwise, the gate insulation layer 11 may be comprised of a tunnel insulation layer, a charge storage layer, and a blocking insulation layer, completing a gate pattern of a floating-trap nonvolatile memory cell.

It can be understood by those skilled in this art that the method according to the invention is applicable to fabricating other kinds of semiconductor devices such as dynamic RAMs or flash memories.

As described above, after performing the high-energy ion implantation process and before beginning a thermal process, a buffer layer is partially removed together with particles or contaminants that may be generated from the ion implantation process. This prevents surface defects on a semiconductor substrate from arising by diffusion of the contaminants during the thermal process.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a semiconductor device, comprising:
forming a buffer layer on a semiconductor substrate;
implanting first impurities into the semiconductor substrate;
removing the buffer layer by a predetermined thickness; and
performing a thermal process to activate the implanted first impurities.

2. The method as set forth in claim 1, further comprising:
forming a photoresist pattern on the buffer layer before implanting the first impurities into the semiconductor substrate; and
removing the photoresist pattern before partially removing the buffer layer by a predetermined thickness,
wherein implanting the first impurities into the semiconductor substrate uses the photoresist pattern as an ion implantation mask.

3. The method as set forth in claim 1, further comprising:
forming a photoresist pattern on the buffer layer before implanting the first impurities into the semiconductor substrate; and
removing the photoresist pattern after partially removing the buffer layer by a predetermined thickness,
wherein implanting the first impurities into the semiconductor substrate uses the photoresist pattern as an ion implantation mask,
wherein removing the buffer layer by the predetermined thickness uses the photoresist pattern as an etch mask.

4. The method as set forth in claim 1, wherein the buffer layer contains contaminants.

5. The method as set forth in claim 1, wherein the predetermined thickness is 10˜60% of the whole thickness of the buffer layer.

6. The method as set forth in claim 1, wherein implanting the first impurities into the semiconductor substrate is carried out at an energy over 800 KeV.

7. The method as set forth in claim 1, after performing the thermal process, further comprising:
removing a remnant portion of the buffer layer from the semiconductor substrate and exposing the semiconductor substrate;
forming a gate insulation layer on the exposed semiconductor substrate;
forming a gate pattern on the gate insulation layer; and
forming source/drain regions adjacent to the gate pattern in the semiconductor substrate.

8. The method as set forth in claim 1, wherein removing the buffer layer by the predetermined thickness is carried out by a wet or dry etching process.

9. The method as set forth in claim 1, wherein the first impurities are N-type, and implanting the first impurities into the semiconductor substrate comprises forming an N-type deep well.

10. The method as set forth in claim 1, before removing the buffer layer by the predetermined thickness, further comprising;
implanting second impurities into the semiconductor substrate at an energy lower than energy for implanting the first impurities into the semiconductor substrate.

11. The method as set forth in claim 10, wherein the energy for the implantation of the second impurities is in a range of 100˜799 KeV.

12. The method as set forth in claim 1, further comprising cleaning a remaining portion of the buffer layer before performing the thermal process.

13. A method of fabricating a semiconductor device, comprising:
forming a buffer layer on a semiconductor substrate;
forming a photoresist pattern on the buffer layer;
implanting first impurities into the semiconductor substrate by using the photoresist pattern as an ion implantation mask;
removing the buffer layer by a predetermined thickness; and
performing a thermal process to activate the implanted first impurities.

14. The method as set forth in claim 13, further comprising:
removing the photoresist pattern before removing the buffer layer by the predetermined thickness.

15. The method as set forth in claim 13, further comprising:
removing the photoresist pattern after removing the buffer layer by the predetermined thickness,
wherein implanting the first impurities into the semiconductor substrate uses the photoresist pattern as an ion implantation mask,
wherein removing the buffer layer by the predetermined thickness uses the photoresist pattern as an etch mask.

16. The method as set forth in claim 13, wherein the buffer layer contains contaminants.

17. The method as set forth in claim 13, wherein the predetermined thickness is 10˜60% of the whole thickness of the buffer layer.

18. The method as set forth in claim 13, wherein implanting the first impurities into the semiconductor substrate is carried out at an energy over 800 KeV.

19. The method as set forth in claim 13, which after performing the thermal process, further comprises:
removing a remnant portion of the buffer layer from the semiconductor substrate and exposing the semiconductor substrate;
forming a gate insulation layer in the exposed semiconductor substrate;
forming a gate pattern on the gate insulation layer; and
forming source/drain regions adjacent to the gate pattern in the semiconductor substrate.

20. The method as set forth in claim 13, wherein the first impurities are N-type, and implanting the first impurities into the semiconductor substrate comprises forming an N-type deep well.

21. The method as set forth in claim 13, before removing the buffer layer by the predetermined thickness, further comprising;
implanting second impurities into the semiconductor substrate at an energy lower than energy for implanting the first impurities into the semiconductor substrate.

22. The method as set forth in claim 13, further comprising cleaning a remaining portion of the buffer layer before performing the thermal process.

23. A method of fabricating a semiconductor device, comprising:
forming a buffer layer on a semiconductor substrate;
forming a photoresist pattern on the buffer layer;
implanting first impurities into the semiconductor substrate using the photoresist pattern as an ion implantation mask;
removing the photoresist pattern to expose the whole surface of the buffer layer;
etching the buffer layer by a predetermined thickness;
cleaning a remaining portion of the buffer layer; and
performing a thermal process to activate the implanted first impurities.

24. The method as set forth in claim 21, wherein the predetermined thickness is 10˜60% of the whole thickness of the buffer layer.

25. The method as set forth in claim 21, wherein the cleaning is performed using a chemical comprised in DIW (Deionized Water) and H₂O₂.
